(19) United States
(12) Patent Application Publication
(10) Pub. No.: US 2008/0001271 A1
(43) Pub. Date: Jan. 3, 2008

(54) Flipped, stacked-chip IC packaging for high bandwidth data transfer buses

(75) Inventor: Walter M. Marcinkiewicz, Chapel Hill, NC (US)

Correspondence Address: COATS & BENNETT/SONY ERICSSON, 1400 CRESCENT GREEN, SUITE 300, CARY, NC, 27511, US

(73) Assignee: Sony Ericsson Mobile Communications AB

(21) Appl. No.: 11/479,873

(22) Filed: Jun. 30, 2006

(51) Int. Cl. H01L 23/02; H01L 21/00

(52) U.S. Cl. 257/678; 438/106

(57) ABSTRACT

Flipped, stacked-chip IC component packaging directly connects first and second IC components, allowing for a virtually unlimited data transfer bus width connecting the two. A first IC component is conventionally affixed to an interposer, and electrical contacts around the periphery thereof wire bonded to interposer pin contacts. A second IC component is mounted to the first IC component in flip chip fashion—with the operative surfaces of the two IC components facing. The electrical contacts formed in the operative services of each IC component are arranged in a corresponding, mirror-image pattern. Conductive bumps are formed on selected electrical contacts on either the first or second IC component prior to cutting individual IC components from a wafer. Any of the flip chip bonding technologies known in the art, or developed in the future, may be advantageously applied to form one or more wide data transfer buses between the two IC components.

### BACKGROUND

The present invention relates generally to the field of integrated circuit component packaging and in particular to a flipped, stacked-chip integrated circuit component packaging method and apparatus.

Integrated circuits (IC) are fabricated by photolithographically marking areas on the surface of a semiconductor substrate (such as silicon), and doping the areas, or introducing impurities via diffusion or ion implantation, to alter the electrical properties of the areas. Insulators and/or metal tracks may be deposited over the doped areas, such as by sputtering, vapor deposition, plating, or the like, to interconnect the doped areas to form electronic components, such as transistors, diodes, and the like, and to interconnect these components into higher-order structures such as latches, registers, ALUs, and the like.

A plurality of identical integrated circuits is formed on a single substrate, or wafer. The wafer is then cut to yield the individual IC components that are then placed on a carrier or interposer. Electrical contacts on the IC component are typically wire-bonded to pin contacts on the interposer, which in turn connect to external pins, balls in a ball grid array, or the like, referred to herein as package contacts. The IC component and wire bonds are often encapsulated in a dielectric material, such as epoxy, for mechanical and thermal protection.

Because the electronic circuits in an integrated circuit are formed in a very thin layer at the surface of a substrate, all electrical contacts are normally formed in this surface, referred to herein as the operative surface. That is, there are no electrical circuits formed into, and in most cases no electrical contacts deposited on, the opposite, or back, side of the substrate, referred to herein as the non-operative surface, or along the edges of the individual IC components (which were cut from a solid wafer). Another IC component packaging technique known in the art is referred to as flip chip packaging, wherein conductive bumps are formed on electrical contacts on the operative surface of an integrated circuit component, usually prior to individual IC components being cut from a wafer. The IC component is then mounted to the interposer in an inverted, or flipped, configuration, with the operative surface facing the interposer. The pin contacts on the interposer surface are positioned to correspond to the electrical contacts and conductive bumps on the IC component. The conductive bumps, or conductive bonding material applied to the conductive bumps, is activated, such as by heat or curing, to establish a permanent electrical and mechanical connection between the flipped chip and the interposer. The interstitial spaces between the conductive bumps may then be filled with a dielectric adhesive, to create a mechanical and thermal connection.

Flip chip packaging is also referred to as Director Connect Assembly (DCA), since the IC component is directly connected to the interposer, obviating the need for wire-bonded connections. IBM introduced flip chip interconnection in the early 1960s for its mainframe computers. Delphi Delco currently places over 300,000 flip chip packages per day into automotive electronics. Most electronic watches, and many portable electronic devices such as cellular phones, pagers, PDAs, GPS receivers, and the like, contain flip chip packaged IC components.

Another high-density IC component packaging technology known in the art is stacked-chip packaging, wherein two or more IC components are stacked within a single package. FIG. 1 depicts a stacked-chip package 10, wherein a first IC component 12 is mounted on an interposer 14. Wire bond connections 16 connect electrical contacts 18 on the operative service 20 of the first IC component 12 to pin connections 22 on the interposer 14. Each pin connection 22 connects to a package contact, such as a BGA ball 24. A second IC component 26 is disposed on the operative surface 20 of the first IC component 12. Wire bond connections 28 connect electrical contacts 30 on the operative surface 32 of the second IC component 26 to electrical contacts 18 on the operative service 20 of the first IC component 12. Wire bond connections 34 connect electrical contacts 30 on the operative surface 32 of the second IC component 26 to pin connections 22 on the interposer 14. A dielectric medium 36, such as epoxy, is formed over the stacked IC components 12, 26 and wire bonds 16, 28, 34. One of the IC components 12, 26 may comprise a processor, and the other of the IC components 12, 26 may comprise a memory device.

Data transfer bandwidth between IC components is often a significant performance bottleneck. In stacked-chip IC component packaging, as depicted in FIG. 1, data transfer bus widths are often limited to 8 or 16 bits. Even with 32-bit buses, powerful (e.g., 64-bit) processors may be limited in performance by their ability to transfer data to and from external (i.e., off-chip) memory. Expansion of data transfer bus widths in stacked-chip IC component packaging is limited, in part, due to the constraint that electrical contacts 18 formed in the operative surface 20 of the first IC component 12 can only be disposed along the periphery thereof. The second IC component 26 precludes the formation of electrical contacts 18 on the majority of the operative surface 20 of the first IC component 12.

### SUMMARY

According to one or more embodiments, flip chip IC component packaging technology is exploited to directly connect first and second IC components, allowing for a virtually unlimited data transfer bus width connecting the two. A first IC component is conventionally affixed to an interposer, and electrical contacts around the periphery thereof wire bonded to interposer pin contacts. A second IC component is mounted to the first IC component in flip chip fashion—that is, with the operative surfaces of the two IC components facing. The electrical contacts formed in the operative services of each IC component are arranged in a corresponding, mirror-image pattern. Either the first or second integrated circuit may have conductive bumps formed on selected electrical contacts prior to cutting individual IC components from a wafer. Any of the flip chip bonding technologies known in the art—or developed in the future—are applicable to the present invention. In one embodiment, one of the IC components may comprise a processor, and the other of the IC components may comprise a memory device.

One embodiment relates to a method of packaging two integrated circuit components to create a data transfer bus between them, each integrated circuit having an operative surface including a plurality of electrical contacts in predetermined positions, and a non-operative surface. Conductive bumps are formed on selected electrical contacts on the operative surface of one of the integrated circuit components. A first integrated circuit component is mounted to an interposer along the non-operative surface of the component. A second integrated circuit component is aligned adjacent the first integrated circuit component such that the operative surfaces of the two integrated circuit components are facing, and such that the conductive bumps form conductive paths between corresponding electrical contacts on the operative surfaces of the two integrated circuit components to form a data transfer bus between the components. The two aligned and electrically connected integrated circuit components are formed into a single integrated circuit package.

Another embodiment relates to an integrated circuit package. The package includes an interposer having a plurality of pin contacts; a first integrated circuit component having an operative surface including a plurality of electrical contacts in predetermined positions; and a second integrated circuit component having an operative surface including a plurality of electrical contacts in corresponding, mirror-image positions to the contacts on the first integrated circuit component. One of the first or second integrated circuit components includes conductive bumps formed onto selected electrical contacts on, its operative surface; and one of the first or second integrated circuit components is affixed to the interposer along its non-operative surface. The integrated circuit component not affixed to the interposer is disposed adjacent the integrated circuit component affixed to the interposer such that the operative surfaces of the two integrated circuit components are facing, and such that the conductive bumps form conductive paths between corresponding electrical contacts on the integrated circuit components to form a data transfer bus between the components.

### BRIEF DESCRIPTION OF DRAWINGS

FIG. 1 is a functional block diagram of a prior art stacked-chip IC component package.

FIG. 2 is a functional block diagram of a flipped, stacked-chip IC component package.

### DETAILED DESCRIPTION

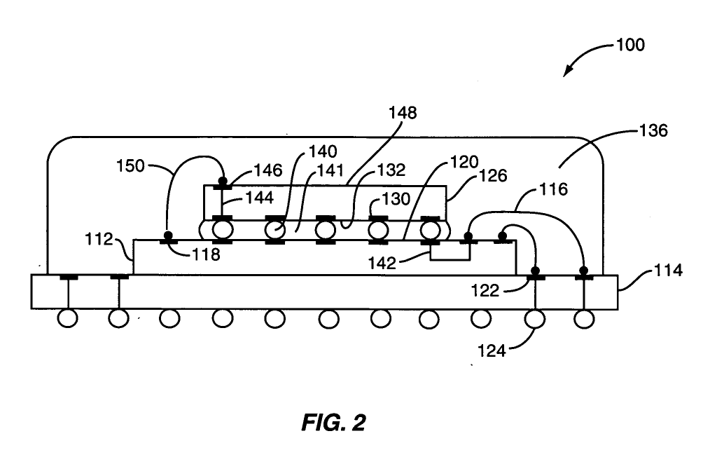

FIG. 2 depicts a flipped, stacked-chip IC component package 100 according to one or more embodiments of the present invention. A first IC component 112 is mounted on an interposer 114. Wire bond connections 116 connect electrical contacts 118 on the operative surface 120 of the first IC component 112 to pin connections 122 on the interposer 114. Each pin connection 122 connects to a package contact, such as a BGA ball 124. A second IC component 126 has electrical contacts 130 formed in an operative surface 132 thereof, in a mirror-image pattern with respect to the electrical contacts 118 formed in the operative surface 120 of the IC component 112. Conductive bumps 140 are formed on the electrical contacts 118, 130 of one of the IC components 112,126. The conductive bumps 140 may be formed on either the IC component 112 attached to the interposer 114, or the IC component 126 that is not attached to the interposer 114. The conductive bumps 140 are preferably formed on the IC component 112, 126 prior to cutting the individual component 112, 126 from a wafer. The conductive bumps 140 may be formed on the IC component 112, 126 in a variety of ways, as discussed herein.

The IC component 126 is disposed over the IC component 112 in a flipped configuration, with the operative surfaces 120, 132 of the two IC components 112, 126 facing, and the respective electrical contacts 118, 130 aligned. The conductive bumps 140 form conductive paths between respective electrical contacts 118, 130 on the two IC components. After the conductive bumps are activated—such as by heat, curing, or the like—the interstitial spaces between the conductive bumps 140, between the IC components 112, 126, may be filled with a dielectric adhesive 141. The adhesive 141 mechanically bonds the IC components 112, 126, and prevents differential thermal expansion. Both IC components 112, 126 and the wire bonds 116 may be encapsulated in a dielectric material 136, such as epoxy, plastic, or the like.

In one embodiment, the IC component 112 provides a conductive path 142 for one or more electrical contacts 130 on the flipped IC component 126 to an interposer 114 pin contact 122. The path is through a conductive bump 140, a corresponding electrical contact 118, the conductive path 142 and a second electrical contact 118 that is wire bonded 116 to the pin contact 122. This provides a path for electrical signals of the flipped IC component 126 to external package contacts 124.

A recent development in integrated circuit fabrication technology is the provision of conductive vias extending through the substrate to the back, or non-operative, side. This allows for wire bonding to either an electrical contact, or pad, formed in a backside metalization process, or in some cases directly to the metal filling the via. In one embodiment, the flipped IC component 126 may include one or more vias 144, each connecting an electrical contact 130 on the operative surface 132 to a corresponding electrical contact 146 on the non-operative surface 148. In another embodiment, the non-operative surface 148 does not include any electrical contacts 146. In either case, a wire bond 150 may electrically connect the via 144 to either an electrical contact 118 on the IC component 112 or a pin contact 122 on the interposer 114.

In the flipped, stacked-chip IC package 100, the entire, two-dimensional surface area of the smaller of the operative surfaces 120, 132 is available to form a data transfer bus between the IC components 112, 126, via corresponding electrical contacts 118, 130 connected by conductive bumps 140. Furthermore, the conductive bumps 140 are short, thus avoiding many of the transmission line effects (e.g., ringing, parasitic capacitance, and the like) of electrical connectors having a greater length, such as wire bonds 116. Accordingly, very wide data transfer buses may easily be formed between the two IC components 112, 126, and may be operated at high frequencies. For example, data transfer buses may be configured as x64, x128, x256, x512, x1024, x2048, and so on. As well known in the art, all other parameters being equal, a wider parallel data transfer bus increases bus bandwidth. In many applications, data transfer bus bandwidth—in particular, bandwidth to memory devices—is a significant performance bottleneck.

As one non-limiting example, the IC component 112 may comprise a processor, and the IC component 126 may comprise a memory device (or vice versa). When the IC components 112, 126 are packaged in the flipped, stacked-chip configuration depicted in FIG. 2, processor performance may be significantly improved by implementing a very wide memory access bus. Of course, other combinations of IC components 112, 126 may advantageously implement wide data transfer buses via a flipped, stacked-chip packaging, such as an integer processor and loading-point coprocessor; a graphics engine and dedicated frame buffer memory; and the like. Those of skill in the art will readily recognize numerous combinations of IC components 112, 126 that may advantageously implement large data transfer bus bit-widths, given the teachings of the present disclosure.

The interconnection between the IC components 112, 126 may be implemented in a wide variety of ways, as known in the traditional flip chip packaging art. In one embodiment, the conductive bumps 140 comprise solder. Solder bump flipped, stacked-chip packaging comprises, in general, preparing a wafer for solder bumping; forming or placing the solder bumps 140; attaching the bumped IC component 112, 126 to the non-bumped IC component 112, 126; filling the interstitial spaces between solder bumps 140 with a dielectric adhesive; attaching one of the IC components 112, 126 to the interposer 114; and wire bonding I/O signals to the interposer pin contacts. These are steps are described in some detail herein, to enable one of ordinary skill in the art to make and use the present invention. Processing for other forms of conductive bumps 140 is similar, and may be readily derived by those of ordinary skill in the art without undue experimentation.

The wafer is prepared for solder bumping—a process referred to as Under Bump Metalization (UBM)—by forming a plurality of special-purpose layers on selected electrical contacts 118, 130. The UBM process may include cleaning, removing one or more insulating aluminum oxide layers, and providing a pad metallurgy that will protect the IC component 112, 126 while making a good mechanical and electrical connection to the solder bump 140. An adhesion layer provides bonding to both the electrical contact 118, 130 metal and the surrounding passivation, providing a strong, low-stress mechanical and electrical connection. A diffusion barrier layer limits the diffusion of solder into the underlying material. A solder wettable layer offers an easily wettable surface to the molten solder during assembly, for good bonding of the solder to the underlying metal. A protective layer may be required to prevent oxidation of the underlying layer.

Solder bumps 140 may be formed or placed on the UBM in many ways, including but not limited to evaporation, electroplating, printing, jetting, stud bumping, and direct placement. Each of these methods may yield different bump size and spacing; require different solder composition; impose different equipment, assembly temperature, and UBM requirements; and have different costs and manufacturing time. Assembly of the IC components 112, 126 may include handling, placing, fluxing, and solder joining operations. Those of skill in the art may adjust the assembly process to account for the bumped IC component 112, 126, the solder bump 140, the assembly equipment, costs, and other factors. Bumped IC components 112, 126 may be placed by fine-pitch surface-mount equipment or by high-accuracy flip chip placement equipment. In either case, the bumped IC component 112, 126 must be aligned with the corresponding, mirror-image patterned electrical contacts 118, 130 on the non-bumped IC component 112, 126 before placement.

Once the IC components 112, 126 are aligned, the solder bumps 140 are activated by heating the solder sufficiently that it flows between the respective electrical contact 118, 130, and upon solidifying, forms a mechanical and electrical connection. A variety of fluxes, with differing application and cleaning requirements, are known in the art to assist the solder flow process. Solder bump 140 activation may be in a belt furnace, by hot gas, or by other means.

One function of the solder bump 140 is to provide a space between the two IC components 112, 126. In one embodiment, this inter-chip space is filled with a dielectric adhesive joining the entire operative surfaces 120, 132 of the two IC components 112, 126. The dielectric adhesive protects the bumps from moisture or other environmental hazards, and provides additional mechanical strength to the assembly. However, its most important purpose, particularly with solder bumps connections on operative surfaces 120, 132 having a large surface area, is to compensate for thermal expansion differences between the two IC components 112, 126. The dielectric adhesive mechanically locks the two IC components 112, 126 together so that differences in thermal expansion do not break or damage the electrical connection of the solder bumps 140. The dielectric adhesive must bond well to the chip passivation on the operative surfaces 120, 132 of both IC components 112, 126. It must also be compatible with the flux. A cleaning step to remove flux residues may be required before applying the dielectric adhesive. The dielectric adhesive may be needle-dispensed along one or two edges of the solder-joined IC components 112, 126. It is drawn into the inter-chip space by capillary action, and may be heat-cured to form a permanent bond.

In one embodiment, the conductive bumps 140 comprise nickel, with a protective layer of gold. The nickel bumps 140 are built up through an electroless plating technique. Most integrated circuit fabrication processes produce an aluminum oxide layer on the electrical contacts 118, 130. This is removed through zinc displacement plating, using a zincate solution, and the conductive bump 140 is then formed by selective electroless plating of nickel in a wet chemical, maskless process. The wafer is cleaned and all exposed metal other than the electrical contacts 118, 130 is passivated or covered with resist. The zincation process removes the native aluminum oxide, and replaces it with a thin layer of zinc.

After zincation, nickel is deposited from a hypophosphate-based nickel bath, with the bump 140 thickness determined by the plating time. Once nickel bumps 140 of a predetermined height have been formed, a thin layer of immersion gold is plated over the zinc to protect the surface from oxidizing. The bumped IC component 112, 126 may be joined to the non-bumped IC component 112, 126 using solder or conductive adhesives. The conductive adhesive may be stenciled onto the non-bumped IC component 112, 126 electrical contacts 118, 130, or the bumped IC component 112, 126 may be dipped into a thin layer of conductive adhesive to coat the conductive bump 140. The electroless Ni—Au bumping process has cost advantages resulting from eliminating the masking and metal sputtering required by some other methods, and from allowing parallel batch processing of multiple wafers, which increases throughput and reduces costs.

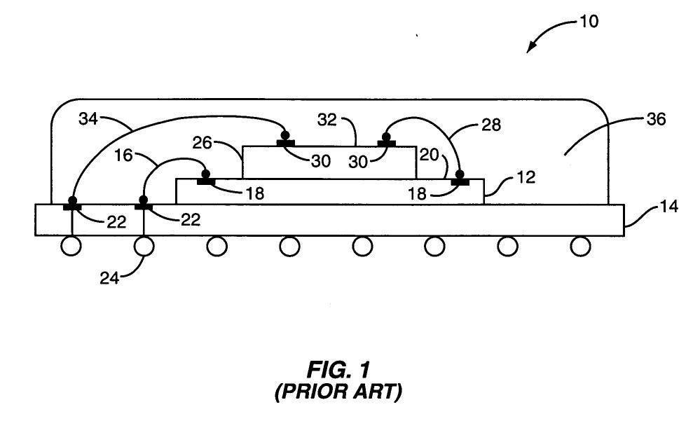

In one embodiment, the conductive bumps 140 comprise gold stud bumps 140 formed by a modified wire bonding process. As known in the art, in generating wire bonds 116, the tip of a gold bond wire is melted to form a small sphere. A wire bonding tool presses this sphere against an aluminum electrical contact 118, 130, applying mechanical force, heat, and ultrasonic energy to create a metallic connection. The wire bonding tool then extends the gold wire to a pin pad 122 on the interposer 114 (or electrical contact 18, 30 of another IC component in traditional stacked-chip packaging, as depicted in FIG. 1), bonds the wire to the pin pad 122, and then breaks off the bond wire. In a modified version of this process, a wire binding tool forms a gold sphere and bonds it to the electrical contact 118, 130. The wire bond tool then breaks off the wire, leaving only a gold stud bump 140. After placement on an IC component 112, 126, the gold stud bumps 140 may be slightly flattened by mechanical pressure to provide a flatter top surface and more uniform bump height, and to press any remaining wire tail into the gold stud bump 140. After aligning the bumped and non-bumped IC components 112, 126, mechanical and electrical operative may be established by use of a conductive adhesive, or by ultrasonically heating the gold stud bumps 140 to bond them to electrical contacts 118, 130 on the non-bumped IC component 112, 126. Gold stud bumping is inexpensive, as wire bonding equipment is widely available and well characterized. Additionally, under-bump metallization (UBM) is not required. However, gold stud bumping is a serial process, which can increase manufacturing time.

In one embodiment, isotropically conductive, silver filled polymers are stencil printed through metal stencils to form conductive, adhesive polymer bumps 140 on the UBM deposited over the electrical contacts 118, 130. The UBM process may comprise zincation to removes the native aluminum oxide and replace it with a thin layer of zinc, followed by plating one or more layers of nickel and a protective immersion layer of gold, as described above. The conductive, adhesive polymer is then stenciled over the electrical contacts 118, 130 of the bumped IC component 112, 126. The polymers may be either thermoset, which cure with heat, or thermoplastic, which soften with heat. Thermoset bumps 140 are activated by heat curing. Thermoplastic bump 140 connections activate in a few seconds. The interstitial spaces between the conductive adhesive bumps 140 may then be filled with a dielectric adhesive.

Various embodiments of the present invention have been described herein to enable those of ordinary skill in the art to make and use the invention. Integrated circuit manufacturing technology, and in particular flip chip packaging technology, advances rapidly, and any technology that advantageously flip mounts an IC component to an interposer may be utilized in the flipped, stacked-chip IC packaging system and method of the present invention. Accordingly, although the present invention has been described herein with respect to particular features, aspects and embodiments thereof, it will be apparent that numerous variations, modifications, and other embodiments are possible within the broad scope of the present invention, and accordingly, all variations, modifications and embodiments, hereby known or not yet invented, are to be regarded as being within the scope of the invention. The present embodiments are therefore to be construed in all aspects as illustrative and not restrictive and all changes coming within the meaning and equivalency range of the appended claims are intended to be embraced therein.

1. A method of packaging two integrated circuit components to create a data transfer bus between them, each integrated circuit component having an operative surface including a plurality of electrical contacts in predetermined positions, and a non-operative surface, comprising:
forming conductive bumps on selected electrical contacts on the operative surface of one of the integrated circuit components;
mounting a first integrated circuit component to an interposer along the non-operative surface of the component;
aligning a second integrated circuit component adjacent the first integrated circuit component such that the operative surfaces of the two integrated circuit components are facing, and such that the conductive bumps form conductive paths between corresponding electrical contacts on the operative surfaces of the two integrated circuit components to form a data transfer bus between the components; and
forming the two aligned and electrically connected integrated circuit components into a single integrated circuit package.

2. The method of claim 1 further comprising wirebonding selected electrical contacts from at least one of the integrated circuit components to pin contacts on the interposer.

3. The method of claim 1 wherein the integrated circuit component not mounted to the interposer includes one or more vias electrically connecting in electrical contact on its operative surface to a point on its non-operative surface, and further comprising wirebonding one or more vias on the non-operative surface to one or more corresponding points selected from the group consisting of electrical contacts on the operative surface of the integrated circuit component mounted to the interposer, and pin contacts on the interposer.

4. The method of claim 3 wherein electrical contacts are formed on the non-operative surface of the integrated circuit component not mounted to the interposer at the point of each via.

5. The method of claim 1 further comprising depositing a dielectric adhesive in the interstitial space between the conductive bumps bridging electrical contacts on the operative services of the two integrated circuit components.

6. The method of claim 1 further comprising encapsulating the two integrated circuit components in a dielectric medium.

7. The method of claim 6 wherein the dielectric medium comprises epoxy.

8. The method of claim 1 further comprising, after aligning the integrated circuit components such that the conductive bumps form conductive paths between the two integrated circuit components, activating the conductive bumps.

9. The method of claim 8 wherein forming conductive bumps on selected electrical contacts on one integrated circuit component comprises depositing solder on the contacts, and wherein activating the conductive bumps comprises heating the solder.

10. The method of claim 8 wherein forming conductive bumps on selected electrical contacts comprises plating metal onto the electrical contacts.

11. The method of claim 10 wherein plating metal onto the electrical contacts comprises electroless plating a predetermined thickness of nickel onto the electrical contacts, and subsequently plating a layer of gold onto the nickel.

12. The method of claim 11 further comprising depositing a conductive bonding material on the nickel-gold conductive bumps prior to aligning the two integrated circuit components.

13. The method of claim 12 wherein the conductive bonding material is solder.

14. The method of claim 13 wherein the conductive bonding material is an electrically conductive adhesive.

15. The method of claim of 8 wherein forming conductive bumps on selected electrical contacts comprises depositing conductive adhesive on the electrical contacts and wherein activating the conductive bumps comprises curing the adhesive.

16. The method of claim 1 wherein depositing conductive bonding material on selected electrical contacts on one of the integrated circuit components comprises depositing a gold stud bump on each selected electrical contact via a modified wire bonding process.

17. An integrated circuit package, comprising:
an interposer having a plurality of pin contacts connected to package contacts;
a first integrated circuit component having an operative surface including a plurality of electrical contacts in predetermined positions;
a second integrated circuit component having an operative surface including a plurality of electrical contacts in corresponding, mirror-image positions to the contacts on the first integrated circuit component;
wherein one of the first or second integrated circuit components includes conductive bumps formed on selected electrical contacts on its operative surface;
wherein one of the first or second integrated circuit components is affixed to the interposer along its non-operative surface; and
wherein the integrated circuit component not affixed to the interposer is disposed adjacent the integrated circuit component affixed to the interposer such that the operative surfaces of the two integrated circuit components are facing, and such that the conductive bumps form conductive paths between corresponding electrical contacts on the integrated circuit components to form a data transfer bus between the components.

18. The integrated circuit package of claim 17, further comprising:
a dielectric adhesive in the interstitial spaces between conductive bumps, between the two integrated circuit components.

19. The integrated circuit package of claim 17, further comprising:
a dielectric medium encapsulating the two integrated circuit components.

20. The integrated circuit package of claim 17, further comprising:
wire bonds between selected electrical contacts on the operative service of at least one integrated circuit component and corresponding pin contacts on the interposer.

21. The integrated circuit package of claim 17 wherein the integrated circuit component not affixed to the interposer includes one or more vias, each forming a conductive path through the integrated circuit component between an electrical contact on the operative surface thereof and a corresponding point on the non-operative surface thereof, and further comprising:
wire bonds between selected vias on the non-operative service of the integrated circuit component not affixed to the interposer and corresponding points selected from the group consisting of electrical contacts on the operative surface of the integrated circuit component affixed to the interposer and pin contacts on the interposer.

22. The integrated circuit package of claim 21 further comprising electrical contacts formed on the non-operative surface of the integrated circuit component not affixed to the interposer, the electrical contact corresponding to the positions of the vias.

23. The integrated circuit package of claim 17 wherein the conductive bumps comprise solder.

24. The integrated circuit package of claim 17 wherein the conductive bumps comprise conductive adhesive.

25. The integrated circuit package of claim 17 wherein the conductive bumps comprise plated nickel with an outer, plated gold layer.

26. The integrated circuit package of claim 17 wherein the conductive bumps comprise gold.

27. The integrated circuit package of claim 17 wherein the first integrated circuit component is a memory device.

28. The integrated circuit package of claim 27 wherein the second integrated circuit component is a processor.
